(19) United States
(12) Patent Application Publication
(10) Pub. No.: US 2026/0324144 A1
(43) Pub. Date: Oct. 15, 2026

(54) SEMICONDUCTOR DEVICE

(71) Applicant: EPISTAR CORPORATION, Hsinchu (TW)

(72) Inventors: Wei Shan YEOH, Hsinchu (TW); Sin-Pei WANG, Hsinchu (TW); Yun-Hung WANG, Hsinchu (TW)

(21) Appl. No.: 19/177,081

(22) Filed: Apr. 11, 2025

(51) Int. Cl. H10H 20/84; H10H 20/82; H10H 20/824

(52) U.S. Cl. CPC H10H 20/84; H10H 20/82; H10H 20/824

(57) ABSTRACT

A semiconductor device includes a transparent base, a semiconductor stack, and an insulation stack. The semiconductor stack is disposed on the transparent base and capable of emitting light with a peak wavelength having a FWHM. The insulation stack includes first sub-layers and second sub-layers alternately stacked. Each of the first sub-layers has a first refractive index, and each of the second sub-layers has a second refractive index different from the first refractive index. The transparent base is located between the insulation stack and the semiconductor stack, the insulation stack has a light emitting surface, and the insulation stack has a light transmittance greater than 90% for light with a wavelength ranging between the peak wavelength plus a half of FWHM and the peak wavelength minus 440 nm.

### BACKGROUND OF THE INVENTION

### Field of the Invention

The present disclosure relates to a semiconductor device, and more particularly, to a semiconductor device capable of emitting light with a wavelength greater than 750 nanometers (nm).

### Description of the Prior Art

Solid-state semiconductor components such as light-emitting diodes (LEDs) have the advantages of low power consumption, low heat energy generation, long working life, shock-proof, small size, fast response speed, and good optoelectronic properties, such as stable luminescence wavelength. Therefore, light-emitting diodes are widely used in household appliances, equipment indicators, displays, etc.

### SUMMARY OF THE INVENTION

According to some embodiments of the present disclosure, a semiconductor device is provided. The semiconductor device includes a transparent base, a semiconductor stack, and an insulation stack. The semiconductor stack is disposed on the transparent base and capable of emitting light with a peak wavelength having a FWHM. The insulation stack includes first sub-layers and second sub-layers alternately stacked. Each of the first sub-layers has a first refractive index, and each of the second sub-layers has a second refractive index different from the first refractive index. The transparent base is located between the insulation stack and the semiconductor stack. The insulation stack has a light emitting surface, and the insulation stack has a light transmittance greater than 90% for light with a wavelength ranging between the peak wavelength plus a half of FWHM and the peak wavelength minus 440 nm.

### BRIEF DESCRIPTION OF THE DRAWINGS

FIG. 1 is a schematic drawing illustrating a system according to some embodiments of the present disclosure.

FIG. 2 is a schematic drawing illustrating a semiconductor device according to some embodiments of the present disclosure.

FIG. 3 is a schematic drawing illustrating an insulation stack according to some embodiments of the present disclosure.

FIG. 4 is a schematic drawing illustrating a reflection spectrum of an insulation stack and spectrum of light emitted from a semiconductor stack according to some embodiments of the present disclosure.

FIG. 5 is a schematic drawing illustrating a semiconductor device bonded to a submount according to some embodiments of the present disclosure.

FIG. 6 is a schematic drawing illustrating a top-view of a semiconductor device according to some embodiments of the present disclosure.

FIG. 7 is a schematic drawing illustrating a top-view of a semiconductor device according to some embodiments of the present disclosure.

FIG. 8 is a schematic drawing illustrating a semiconductor device bonded to a submount according to some embodiments of the present disclosure.

FIG. 9 is a schematic drawing illustrating a semiconductor stack according to some embodiments of the present disclosure.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the related art that the present disclosure can also be employed in a variety of other applications.

It should be understood that, although the terms first, second, etc. may be used herein to describe various elements, components, regions, layers and/or sections, these elements, components, regions, layers and/or sections should not be limited by these terms. These terms are only used to distinguish one element, component, region, layer and/or section from another. Thus, a first element, component, region, layer or section discussed below could be termed a second element, component, region, layer or section without departing from the teachings of the disclosure.

In the present disclosure, if not otherwise specified, the general formula InGaP represents Inₓ₁Ga₁₋ₓ₁P, wherein 0<x1<1; the general formula AlGaInP represents Alₓ₂Gaₓ₃In₁₋ₓ₂₋ₓ₃P, wherein 0<x2<1 and 0<x3<1; the general formula InGaAsP represents Inₓ₄Ga₁₋ₓ₄Asₓ₅P₁₋ₓ₅, wherein 0<x4<1, 0<x5<1; the general formula AlGaInAs represents Alₓ₆Gaₓ₇In₁₋ₓ₆₋ₓ₇As, wherein 0<x6<1 and 0<x7<1; the general formula InGaAs represents Inₓ₈Ga₁₋ₓ₈As, wherein 0<x8<1; the general formula AlGaAs represents Alₓ₉Ga₁₋ₓ₉As, wherein 0<x9<1; the general formula AlGaAsP represents Alₓ₁₀Ga₁₋ₓ₁₀Asₓ₁₁P₁₋ₓ₁₁, wherein 0<x10<1 and 0<x11<1; the general formula AlGaN represents Alₓ₁₁Ga₁₋ₓ₁₁As, wherein 0<x11<1, AlGaN; the general formula InGaN represents Inₓ₁₂Ga₁₋ₓ₁₂N, wherein 0<x12<1; the general formula AlGaInN represents Alₓ₁₃Gaₓ₁₄In₁₋ₓ₁₃₋ₓ₁₄N, wherein 0<x13<1 and 0<x14<1; the general formula AlInP represents Alₓ₁₅In₁₋ₓ₁₅P, wherein 0<x15<1; the general formula InGaNAs represents Inₓ₁₆Ga₁₋ₓ₁₆Nₓ₁₇As, wherein 0<x16<1 and 0<x17<1

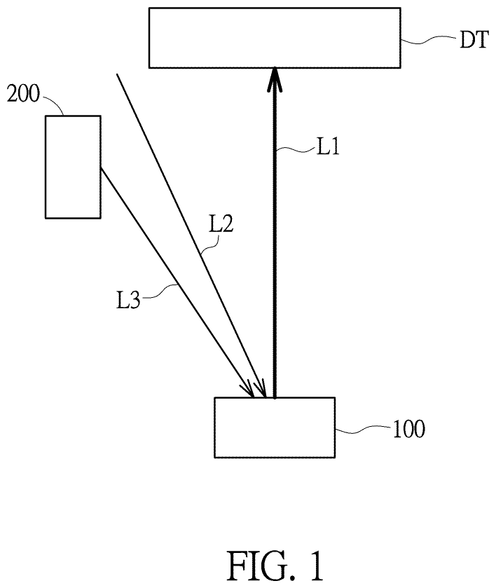

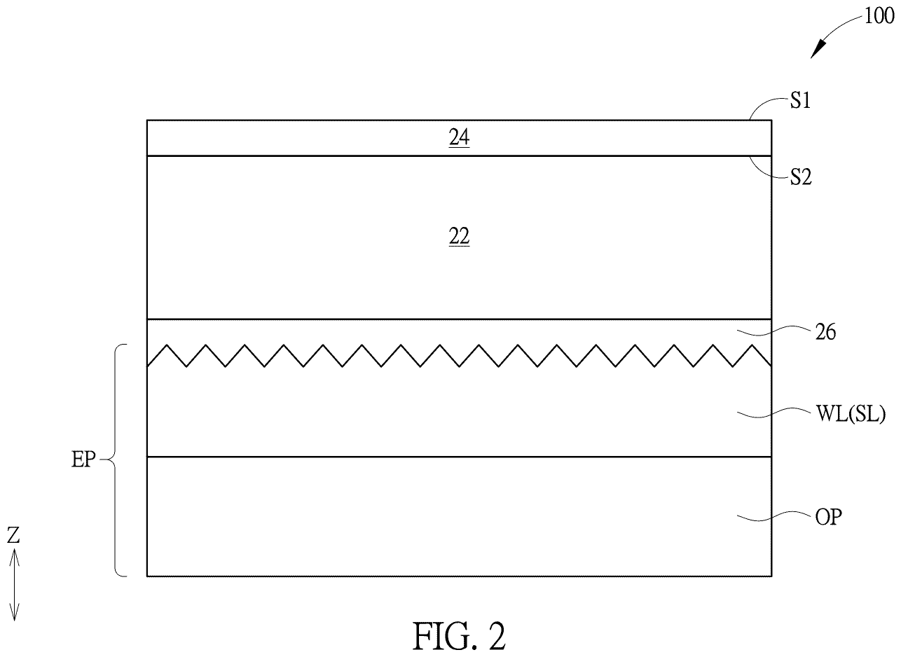

FIG. 1 is a schematic drawing illustrating a system according to some embodiments of the present disclosure. FIG. 2 is a schematic drawing illustrating a semiconductor device according to some embodiments of the present disclosure. As illustrated in FIG. 1, the system may include a semiconductor device 100 and a detector DT. The semiconductor device 100 may be capable of emitting light L1 with a wavelength greater than 750 nm, such as infrared light with wavelength ranging from 750 nm to 1000 nm. The light L1 may be used as a signal, and the detector DT may receive the light L1 and be used as a signal receiver.

As shown in FIG. 2, in some embodiments, the semiconductor device 100 is a light-emitting device and the semiconductor device 100 may include a transparent base 22, a semiconductor stack EP, and an insulation stack 24. The transparent base 22 is disposed on the semiconductor stack EP, and the insulation stack 24 is disposed on the transparent base 22. The semiconductor stack EP is capable of emitting light with a wavelength greater than 750 nm. The insulation stack 24 has a top surface S1, and the insulation stack 24 has a light transmittance greater than 90% for light passing the top surface S1 with a wavelength greater than 500 nm.

In some embodiments, a vertical direction Z may be regarded as a thickness direction of the transparent base 22. The insulation stack 24 and the semiconductor stack EP may be disposed at two opposite sides of the transparent base 22 in the vertical direction Z. The insulation stack 24 may include the top surface S1 which is defined as a light emitting surface and a bottom surface S2 opposite to the top surface S1 in the vertical direction Z. The bottom surface S2 may face and/or contact the transparent base 22. In some embodiments, the transparent base 22 may include a substrate for epitaxial growth, a substrate for bonding with the semiconductor stack EP, and/or a carrier substrate. A material of the transparent base 22 may include sapphire, glass, quartz, GaAs, and GaP and a thickness of the transparent base 22 may range from 60 micrometers (um) to 150 um.

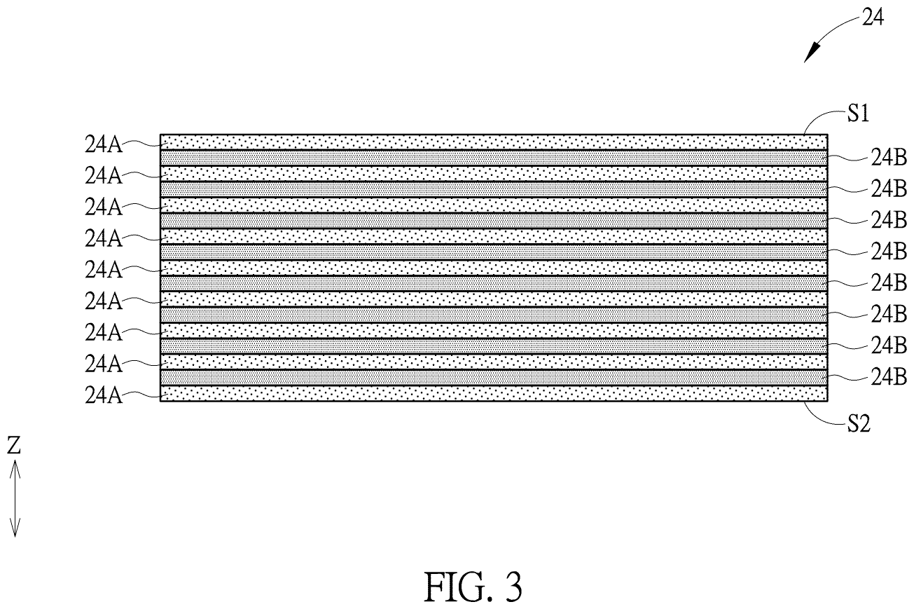

FIG. 3 is a schematic drawing illustrating the insulation stack 24 according to some embodiments of the present disclosure. As illustrated in FIG. 2 and FIG. 3, in some embodiments, the insulation stack 24 may include first sub-layers 24A and second sub-layers 24B alternately stacked in the vertical direction Z. Each of the first sub-layers 24A has a first refractive index, and each of the second sub-layers 24B has a second refractive index different from the first refractive index. In some embodiments, the second refractive index may be greater than the first refractive index. One of the first sub-layers 24A may be the topmost layer in the insulation stack 24, and another one of the first sub-layers 24A may be the bottommost layer in the insulation stack 24. In some embodiments, a refractive index of the transparent base 22 may be greater than the first refractive index and less than the second refractive index. In some embodiments, the first refractive index ranges from 1.44 to 1.5 and the second refractive index ranges from 1.8 to 2.6.

In some embodiments, when the topmost layer has the first refractive index close to the refractive index of air, light emitted from the semiconductor stack EP may easily pass through the topmost layer. When the bottommost layer has the first refractive index less than the refractive index of the transparent base 22, the bottommost layer may have better reflectivity. Each of the first sub-layers 24A may include Silicon Oxide, Magnesium Fluoride (MgF₂), Barium Fluoride (BaF₂), or other suitable dielectric materials, and each of the second sub-layers 24B may include Titanium Oxide (TiOₓ), Tantalum Pentoxide (Ta₂O₅), Hafnium Oxide (HfO₂), Niobium Pentoxide (Nb₂O₅), Silicon Nitride (SiNx), Zirconium dioxide (ZrO2), or other suitable materials. In some embodiments, a thickness of the insulation stack 24 may range from 1500 nm to 3000 nm.

In some embodiments, a light absorptance of the insulation stack 24 may be neglected, and the sum of the light transmittance of the insulation stack 24 for light with a specific wavelength range and a reflectance of the insulation stack 24 for the light may be substantially equal to 100%. In some embodiments, the semiconductor stack EP emits visible or invisible light with a peak wavelength, the insulation stack 24 may have the light transmittance greater than or equal to 90% for ambient light or light emitted from other emitters having the wavelength ranging between the peak wavelength plus a half of FWHM (full width at half maximum) s and the peak wavelength minus 440 nm (such as minus 250 nm, minus 150 nm). Or, the insulation stack 24 has a light reflectance less than or equal to 10% for ambient light or light emitted from other emitters having the wavelength ranging between the peak wavelength plus the half of FWHM and the peak wavelength minus 440 nm (such as minus 250 nm, minus 150 nm).

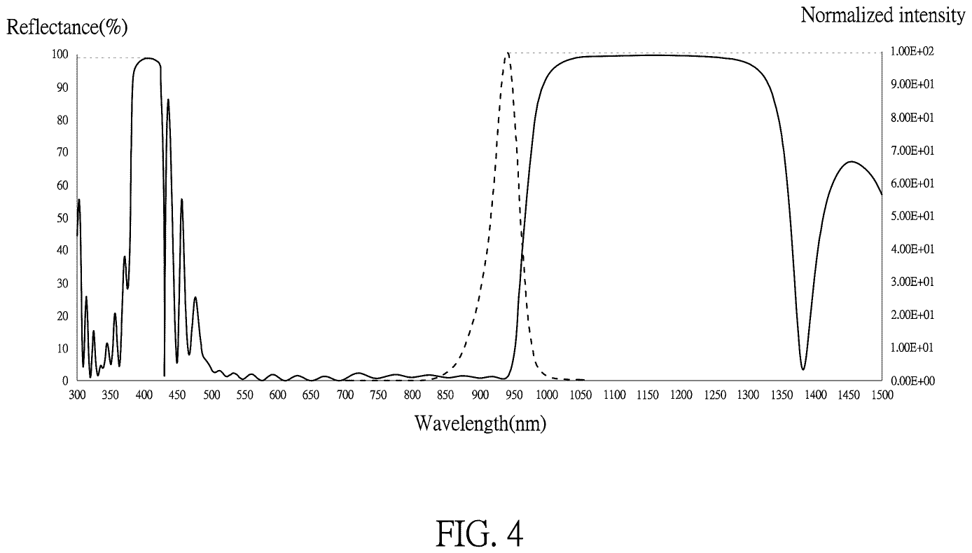

FIG. 4 is a schematic drawing illustrating a reflection spectrum of the insulation stack 2 and a spectrum of light emitted from the semiconductor stack EP according to some embodiments of the present disclosure. As shown in FIGS. 2-4, in some embodiments, the semiconductor stack EP emits light with a peak wavelength of 940 nm with a FWHM 80 nm (and the half of FWHM is 40 nm) and the insulation stack 24 may have a light reflectance less than or equal to 10% for light with a wavelength ranging from 500 nm (that is 940 nm-440 nm) to 980 nm (that is 940 nm+40 nm), and the insulation stack 24 may have a light transmittance greater than or equal to 90% for light with a wavelength ranging from 500 nm to 980 nm. The insulation stack 24 may be regarded as an anti-reflection stack for light with a wavelength ranging from 500 nm to 980 nm. Therefore, light with the wavelength within the range from 500 nm to 980 nm can all substantially pass through the insulation stack 24, and the light transmittances of the insulation stack 24 for light with the wavelength within the range from 500 nm to 980 nm are all greater than 90%.

In some embodiments, for example, the peak wavelength of the semiconductor stack EP may be 450 nm, the optical thickness of each of the first sub-layers 24A and the second sub-layers 24B of the insulation stack 24 may be adjusted accordingly, so that the insulation stack 24 may have the light transmittance greater than 90% for light with a wavelength ranging between the peak wavelength plus a half of FWHM and the peak wavelength minus 250 nm, which falls within UV light wavelength, and the UV light can be absorbed by the semiconductor stack EP. Similarly, if the semiconductor stack EP emits light with the peak wavelength ranging between 1000 nm to 2000 nm, the optical thickness of each of the first sub-layers 24A and the second sub-layers 24B of the insulation stack 24 may be also adjusted accordingly, so that the insulation stack 24 may have a light transmittance greater than or equal to 90% for light with a wavelength ranging between the peak wavelength plus a half of FWHM and the peak wavelength minus 250 nm, which falls within red or infrared red light wavelength, and the red or infrared red light can be absorbed by the semiconductor stack EP.

In some embodiments, the semiconductor stack EP may emit light with the peak wavelength, and the insulation stack 24 may have a light transmittance less than 10% for light with a wavelength larger than the peak wavelength plus 150 nm. In some embodiments, the semiconductor stack EP may emit light with the peak wavelength, and the insulation stack 24 may have a light transmittance less than 10% for light with a wavelength ranging between the peak wavelength plus 150 nm and the peak wavelength plus 250 nm. In other words, the insulation stack 24 may have a light reflectance greater than 90% for light with a wavelength larger than the peak wavelength plus 150 nm or ranging between the peak wavelength plus 150 nm and the peak wavelength plus 250 nm.

As shown in FIGS. 2 and 4, in some embodiments, the peak wavelength described above may be 940 nm, the insulation stack 24 may have a light reflectance greater than 90% for light with a wavelength ranging between 1090 nm and 1190 nm, and the insulation stack 24 may have a light transmittance less than 10% for light with a wavelength ranging between 1090 nm and 1190 nm. The insulation stack 24 may be used to reduce the field of view (FOV) of the light-emitting device and improve radiant intensity of the light-emitting device. In other words, the viewing angle of the light emitted by the semiconductor stack EP can be effectively reduced.

As illustrated in FIG. 2, in some embodiments, the semiconductor device 100 may further optionally include a bonding layer 26 disposed between the transparent base 22 and the semiconductor stack EP, and the semiconductor stack EP may include a window layer WL and other semiconductor epitaxial layers OP. The window layer WL may be disposed between the bonding layer 26 and the other semiconductor epitaxial layers OP of the semiconductor stack EP. The window layer WL may optionally have a roughed surface and is used for current spreading. A refractive index of the bonding layer 26 may be less than a refractive index of the transparent base 22, and a refractive index of the window layer WL may be greater than the refractive index of the bonding layer 26.

The bonding layer 26 may include silicon oxide, aluminum oxide, benzocyclobutene (BCB), or other suitable bonding materials, and a thickness of the bonding layer 26 may range from 1000 nm to 3500 nm. In some embodiments, the window layer WL may absorb the light with a wavelength less than the peak wavelength of light emitted by the semiconductor stack EP and has a thickness greater than 1 um and less than or equal to 8 um. In some embodiments, the window layer WL may include group III-V materials such as Gallium Phosphide (GaP), Aluminum Gallium Arsenide (AlGaAs), Aluminum Indium Phosphide (AlInP) Gallium Arsenide (GaAs), Aluminum Indium Gallium Arsenide (AlInGaAs), Aluminum Gallium Indium Phosphide (AlGaInP), Gallium Nitride (GaN), Aluminum Gallium Nitride (AlGaN), Indium Gallium Nitride (InGaN), Aluminum Gallium Indium Nitride (AlGaInN), Indium Gallium Nitride Arsenide (InGaNAs) or other suitable semiconductor material.

In some embodiments, the window layer WL may be made by ternary nitride semiconductor, such as the above-mentioned group III-V materials. In some embodiments, the window layer WL may include Alₓ₅Ga₁₋ₓ₅As, where 0<x5<0.3. While the Aluminum composition ratio x5 of the window layer is less than 0.3, a direct band gap of the window layer WL may be less than 1.8 eV and the window layer WL may be capable of absorbing a light with a wavelength less than the peak wavelength of light emitted by the semiconductor stack EP (such as a wavelength less than 690 nm).

In some embodiments, the window layer WL may be a single layer or have a plurality of semiconductor sub-layers SLs. One of the semiconductor sub-layers SLs may include materials such as Gallium Phosphide (GaP), and the one of the semiconductor sub-layers SLs may have the roughed surface for directly contacting and/or bonding to the bonding layer 26 for improving adhesion therebetween. A refractive index of the bonding layer 26 may be less than a refractive index of the transparent base 22, and a refractive index of the one or each of the semiconductor sub-layers SLs may be greater than the refractive index of the bonding layer 26. The semiconductor sub-layers SLs may include Gallium Phosphide (GaP), Aluminum Gallium Arsenide (AlGaAs), Aluminum Indium Phosphide (Alₓ₂₁In₁₋ₓ₂₁P, where 0.4<x21<0.6), or Aluminum Gallium Indium Phosphide((Alₓ₃₁Ga₁₋ₓ₃₁)ₓ₄₁In₁₋ₓ₄₁P, where 0<x31<1, 0.4<x41<0.6).

In some embodiments, the Aluminum composition ratio of the window layer WL may be decreased for decreasing the bandgap of the window layer WL for absorbing longer wavelength. In some embodiments, with the insulation stack 24 having the light reflectance or light transmittance described above, the window layer WL may be capable of absorbing light entering the semiconductor device 100 with a wavelength less than the peak wavelength.

By using the insulation stack 24 for reducing stray/ambient light (such as light L2 illustrated in FIG. 1) and/or light from other emitters (such as light L3 from another emitter 200 illustrated in FIG. 1) reflected by the semiconductor device 100 and by using the window layer WL for absorbing undesired light (with a wavelength less than the peak wavelength of the semiconductor stack EP), related problems such as crosstalk and/or noise for a detector receiving light from the semiconductor device 100 may be improved accordingly.

The following description will detail the different embodiments of the present disclosure. To simplify the description, the following description will detail the dissimilarities among different embodiments and the identical features will not be redundantly described. In addition, identical components in each of the following embodiments are marked with identical symbols for making it easier to understand the differences between the embodiments.

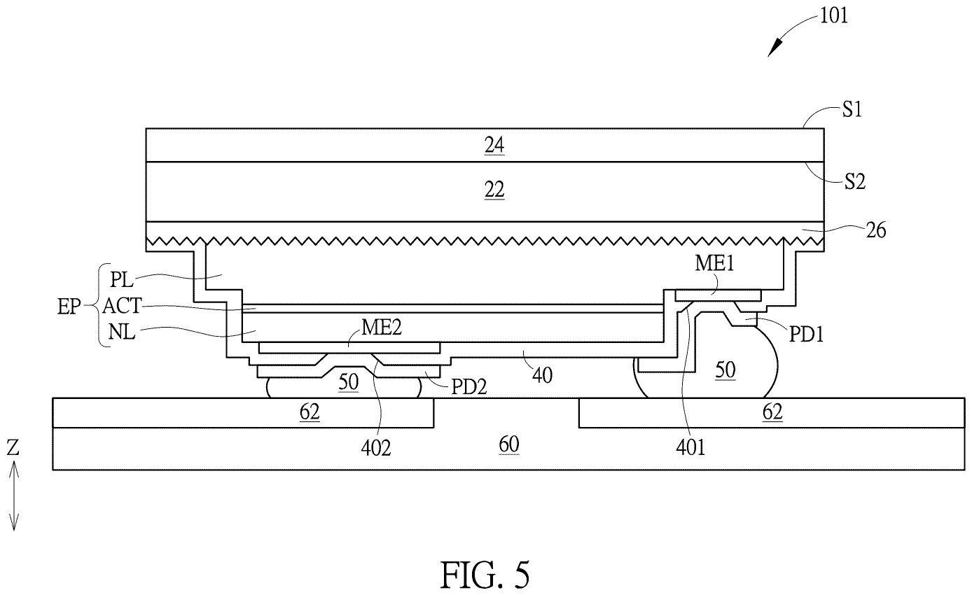

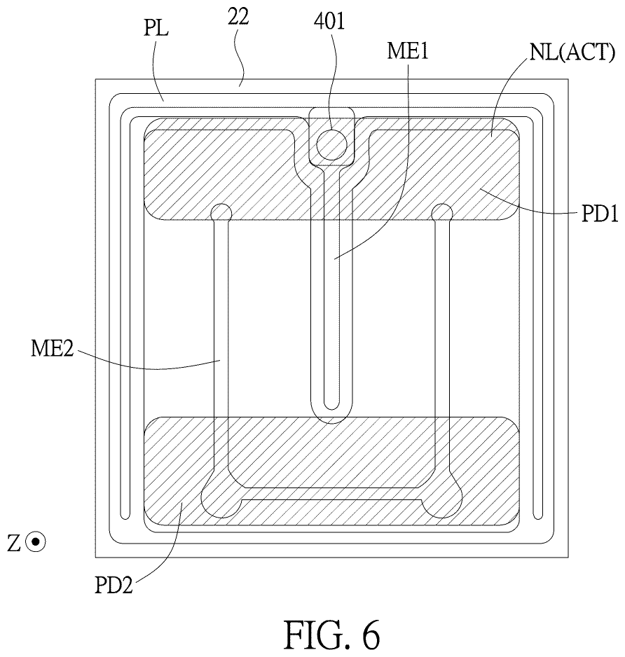

FIG. 5 is a schematic drawing illustrating a semiconductor device 101 bonding to a submount which may be a driving substrate 60 according to some embodiments of the present disclosure. FIG. 6 is a schematic drawing illustrating a top-view of a semiconductor device according to some embodiments of the present disclosure. In some embodiments, FIG. 6 may be regarded as a drawing illustrating the semiconductor device 101 in FIG. 5 and viewed from the side of the pads in FIG. 5. As shown in FIG. 5, in the semiconductor device 101, the semiconductor stack EP may include a first semiconductor structure PL, a second semiconductor structure NL, and an active structure ACT sandwiched between the first semiconductor structure PL and the second semiconductor structure NL. The first semiconductor structure PL may be disposed between the active structure ACT and the bonding layer 26 in the vertical direction Z. In some embodiments, the first semiconductor structure PL may be a p-type semiconductor structure including a plurality of epitaxial semiconductor layers stacked in the vertical direction Z, and the second semiconductor structure NL may be an n-type semiconductor structure including a plurality of epitaxial semiconductor layers stacked in the vertical direction Z.

In some embodiments, the active structure ACT may include a multiple-quantum well (MQW, not shown) including well layers and barrier layers which are alternately stacked. The well and barrier layers each may include group III-V binary, ternary or quaternary compound semiconductor materials such as Indium Gallium Arsenide (InGaAs), Aluminum Gallium Arsenide (AlGaAs), Indium Gallium Phosphide (InGaP), Aluminum Indium Phosphide (AlInP), Aluminum Indium Gallium Phosphide (AlGaInP), Indium Gallium Arsenide Phosphide (InGaAsP), Aluminum Gallium Arsenide Phosphide (AlGaAsP), Gallium Nitride (GaN), Indium Gallium Nitride (InGaN), or Aluminum Gallium Nitride (AlGaN), Aluminum Gallium Indium Nitride (AlGaInN), Indium Gallium Nitride Arsenide (InGaNAs). In some embodiments, the bandgap of the barrier layers is greater than the bandgap of the well layers. A thickness of each of the well layers each may range from 2 nm to 20 nm, and the total thickness of the active structure ACT may range from 50 nm to 700 nm. By means of adjusting the Indium composition ratio or the thickness of the well layers, the peak wavelength of light emitted by the semiconductor stack EP may be adjusted accordingly.

As shown in FIG. 5, the semiconductor device 101 may further include a first contact structure ME1, a second contact structure ME2, a dielectric structure 40, a pad structure PD1, a pad structure PD2, connection structures 50 (e.g., solder balls), conductive lines 62 (e.g., metallic traces), and a driving substrate 60. The first contact structure ME1 may be disposed on and connected with the first semiconductor structure PL, and the second contact structure ME2 may be disposed on and connected with the second semiconductor structure NL. The dielectric reflective structure 40 may cover the semiconductor stack EP.

The dielectric structure 40 may have a reflectance greater than 90% for the light emitted by the active structure ACT and include a single layer or a plurality of layers. The single layer includes Silicon Oxide or Silicon Nitride, while the plurality of layers may be a Distributed Bragg reflector (DBR) including high refractive index layers (e.g. Titanium Oxide (TiOₓ), Tantalum Pentoxide (Ta₂O₅), Hafnium Oxide (HfO₂), Niobium Pentoxide (Nb₂O₅), Silicon Nitride (SiNx), Zirconium dioxide (ZrO2)) and low refractive index layers (e.g., Silicon Oxide (SiO2), Magnesium Fluoride (MgF₂), Barium Fluoride (BaF₂)) which are alternately stacked.

The dielectric structure 40 may include openings to expose the first contact structure ME1 and the second contact structure ME2. The pad structure PD1 is disposed on the dielectric structure 40 and filled into a first opening 401 of the dielectric structure 40 to connect the first contact structure ME1, and the pad structure PD1 is electrically connected with the first semiconductor structure PL via the first contact structure ME1. The pad structure PD2 is disposed on the dielectric structure 40 and filled into a second opening 402 of the dielectric structure 40 to connect the second contact structure ME2 and the pad structure PD2 is electrically connected with the second semiconductor structure NL via the first contact structure ME2.

The first contact layer ME1 and the second contact layer ME2 are used for reducing contact resistance between the pad structure PD1, PD2 and the semiconductor stack EP. The pad structure PD1 and the pad structure PD2 may be electrically connected with the corresponding conductive lines 62 on the driving substrate 60, respectively, via the connection structures 50, and the driving substrate 60 may be electrically connected with the first semiconductor structure PL and the second semiconductor structure NL, accordingly. In some embodiments, the first contact structure ME1 may include metals such as gold (Au), titanium (Ti), platinum (Pt), gold-beryllium alloy (BeAu), or other suitable conductive metals, and the second contact structure ME2 may include metals such as gold, titanium, platinum, gold-germanium alloy (GeAu), or other suitable conductive metals.

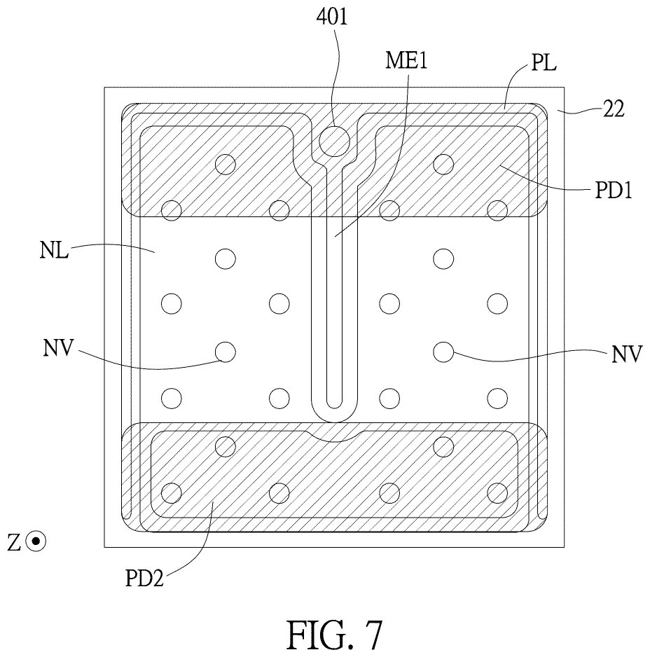

FIG. 7 is a schematic drawing illustrating a top-view of a semiconductor device 102 according to some embodiments of the present disclosure. In FIG. 7, the semiconductor device 102 is devoid of the second contact structure ME2 and an additional dielectric structure (not shown) is disposed between the second semiconductor structure NL and the dielectric structure 40. The additional dielectric structure has a plurality of vias NV to uncover the second semiconductor structure NL.

A conductive structure (not shown) is disposed on the additional dielectric structure and extends into the plurality of vias NV to physically and electrically connect to the second semiconductor structure NL. The pad structure PD1 is filled into the first opening 401 of the dielectric structure 40 to connect the first contact structure ME1. The pad structure PD2 is filled into a second opening 402 of the dielectric structure 40 to connect the conductive structure and the pad structure PD2 is electrically connected with the second semiconductor structure NL via the conductive structure.

The additional dielectric structure includes a material referring to the dielectric structure 40 and has the material same as or different from that of the dielectric structure 40. The conductive structure includes metal such as Ag, Au, Al, Ti, Cr, Pt and other suitable metals.

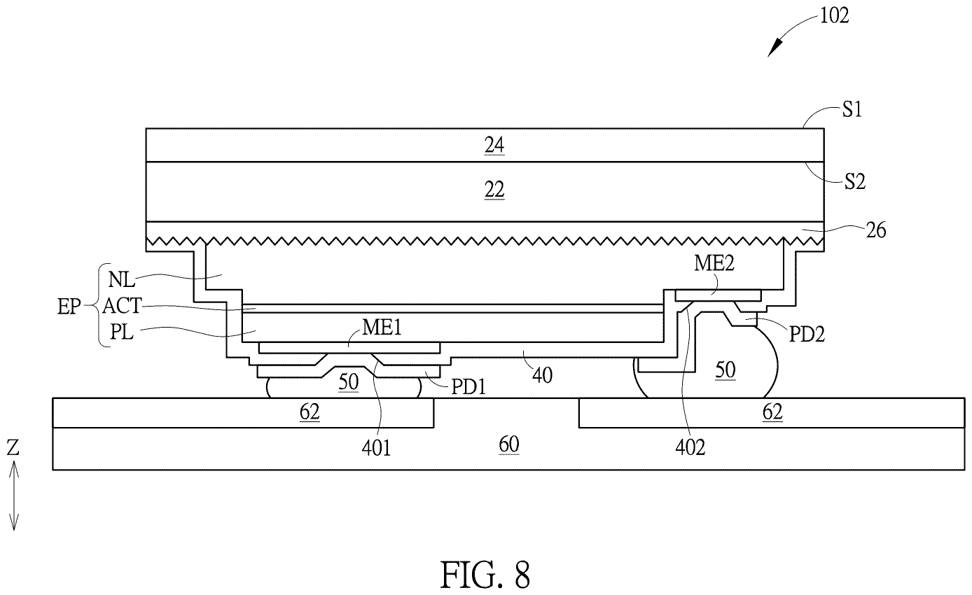

FIG. 8 is a schematic drawing illustrating a semiconductor device 102 according to another embodiment of the present disclosure. The semiconductor device 102 has a structure similar with the semiconductor device 101. In the embodiment, the second semiconductor structure NL may be disposed between the bonding layer 26 and the active structure ACT. In some embodiments, the second semiconductor structure NL may include the above-mentioned window layer.

While the semiconductor device 102 has a top-view of FIG. 7, the semiconductor device 102 is devoid of the first contact structure ME1 and the additional dielectric structure has a plurality of vias NV to uncover the first semiconductor structure PL. The conductive structure (not shown) is disposed on the additional dielectric structure and extends into the plurality of vias NV to physically and electrically connect to the first semiconductor structure PL. The pad structure PD1 is filled into the first opening 401 of the dielectric structure 40 to connect the conductive structure and the pad structure PD1 is electrically connected with the first semiconductor structure PL via the conductive structure. The pad structure PD2 is filled into the second opening 402 of the dielectric structure 40 to connect the second contact structure ME2.

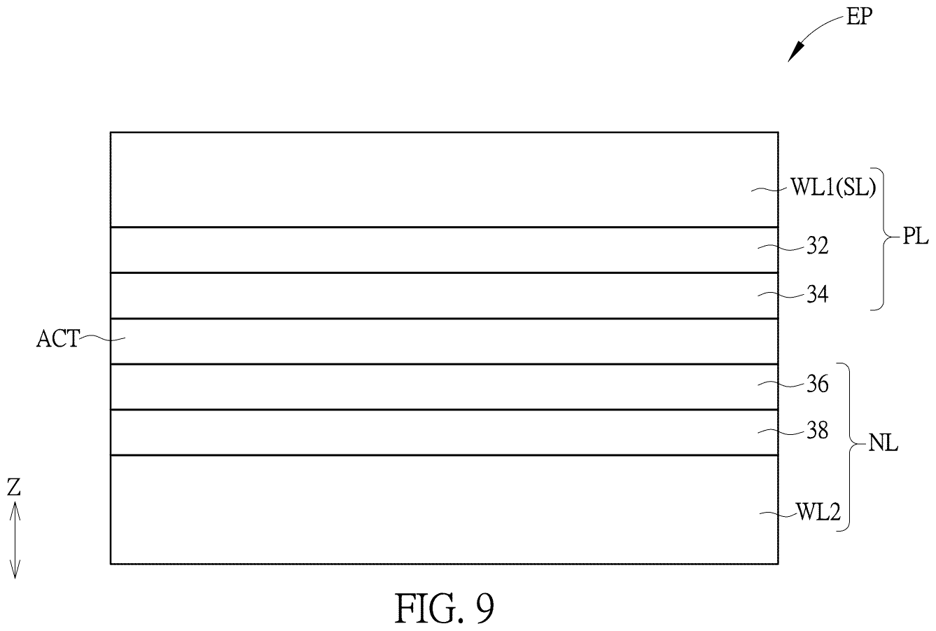

FIG. 9 is a schematic drawing illustrating the semiconductor stack EP according to some embodiments of the present disclosure. As shown in FIG. 5 and FIG. 9, in some embodiments, the first semiconductor structure PL may optionally include a first window layer WL1, a cladding layer 32, and a confine layer 34. The cladding layer 32 and the confine layer 34 may be disposed between the first window layer WL1 and the active structure ACT, and the confine layer 34 may be disposed between the cladding layer 32 and the active structure ACT. The cladding layer 32 may be used as a hole carrier injection layer in the first semiconductor structure PL, and the confine layer 34 may be used as a hole confine layer in the first semiconductor structure PL. The cladding layer 32 and the confine layer 34 may include Aluminum Gallium Arsenide or other suitable semiconductor materials, and an Aluminum composition ratio of the confine layer 34 may be less than that of the cladding layer 32, and the Aluminum composition ratio of the first window layer WL1 is less than the Aluminum composition ratio of the cladding layer 32. A thickness of the confine layer 34 may range from 100 nm to 600 nm, and a thickness of the cladding layer 32 may range from 100 nm to 500 nm.

As shown in FIG. 9, in some embodiments, the second semiconductor structure NL may optionally include a second window layer WL2, a confine layer 36, and a cladding layer 38. The active structure ACT may be disposed between the first window layer WL1 and the second window layer WL2 in the vertical direction Z. The confine layer 36 and the cladding layer 38 may be disposed between the active structure ACT and the second window layer WL2, and the confine layer 36 may be disposed between the active structure ACT and the cladding layer 38. The cladding layer 38 may be used as an electron carrier injection layer in the second semiconductor structure NL, and the confine layer 36 may be used as an electron confine layer in the second semiconductor structure NL. A thickness of the second window layer WL2 in the second semiconductor structure NL may range from 1 um to 4 um. The cladding layer 38 and the confine layer 36 may include Aluminum Gallium Arsenide or other suitable semiconductor materials, and an Aluminum composition of the confine layer 36 may be less than that of the cladding layer 38. A thickness of the confine layer 36 may range from 100 nm to 600 nm, and a thickness of the cladding layer 38 may range from 100 nm to 500 nm. The first and second window layer WL1, WL2 may be used as a current spreading layer in the semiconductor stack EP.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A semiconductor device, comprising:
a transparent base;
a semiconductor stack disposed on the transparent base and capable of emitting light with a peak wavelength having a FWHM; and
an insulation stack comprising first sub-layers and second sub-layers alternately stacked, wherein each of the first sub-layers has a first refractive index, and each of the second sub-layers has a second refractive index different from the first refractive index,
wherein the transparent base is located between the insulation stack and the semiconductor stack, the insulation stack has a light emitting surface, and the insulation stack has a light transmittance greater than 90% for light with a wavelength ranging between the peak wavelength plus a half of the FWHM and the peak wavelength minus 440 nm.

2. The semiconductor device according to claim 1, wherein the semiconductor stack comprises an active structure and a window layer, and the window layer is disposed between the active structure and the transparent base.

3. The semiconductor device according to claim 2, wherein a thickness of the window layer is greater than 1 um.

4. The semiconductor device according to claim 3, wherein the thickness of the window layer is less than or equal to 8 um.

5. The semiconductor device according to claim 1, wherein the window layer comprises Aluminum Gallium Arsenide (AlGaAs), Gallium Arsenide (GaAs), or Aluminum Indium Gallium Arsenide (AlInGaAs).

6. The semiconductor device according to claim 1, wherein the window layer comprises an Aluminum composition ratio less than or equal to 0.3.

7. The semiconductor device according to claim 1, wherein a direct band gap of the window layer is less than 1.8 eV.

8. The semiconductor device according to claim 1, further comprising a bonding layer disposed between the transparent base and the semiconductor stack,

9. The semiconductor device according to claim 8,
wherein a refractive index of the bonding layer is less than a refractive index of the transparent base.

10. The semiconductor device according to claim 8, wherein the bonding layer comprises silicon oxide, aluminum oxide, or benzocyclobutene (BCB).

11. The semiconductor device according to claim 8, wherein the window layer further comprises a semiconductor sub-layer bonding to the bonding layer, and a refractive index of the semiconductor sub-layer is greater than the refractive index of the bonding layer.

12. The semiconductor device according to claim 11, wherein the semiconductor sub-layer comprises gallium phosphide (GaP).

13. The semiconductor device according to claim 1, wherein the second refractive index is greater than the first refractive index, and a refractive index of the transparent base is greater than the first refractive index and less than the second refractive index.

14. The semiconductor device according to claim 1, wherein the first refractive index ranges from 1.44 to 1.5.

15. The semiconductor device according to claim 1, wherein the second refractive index ranges from 1.8 to 2.6.

16. The semiconductor device according to claim 1, wherein each of the first sub-layers comprises silicon oxide, magnesium fluoride (MgF₂), or barium fluoride (BaF₂).

17. The semiconductor device according to claim 1, wherein each of the second sub-layers comprises titanium oxide (TiO₂), tantalum pentoxide (Ta₂O₅), hafnium oxide (HfO₂), niobium pentoxide (Nb₂O₅), or silicon nitride.

18. The semiconductor device according to claim 1, wherein the insulation stack has a light transmittance less than 10% for light with a wavelength ranging between the peak wavelength plus 150 nm and the peak wavelength plus 250 nm.

19. The semiconductor device according to claim 18, wherein the insulation stack has the light transmittance less than 10% for light with a wavelength ranging between 1090 nm and 1190 nm.

20. The semiconductor device according to claim 1, wherein the second refractive index is greater than the first refractive index, one of the first sub-layers is a topmost layer in the insulation stack, and another one of the first sub-layers is a bottommost layer in the insulation stack.
